(19) United States
(12) Patent Application Publication
(10) Pub. No.: US 2026/0367518 A1
(43) Pub. Date: Nov. 19, 2026

(54) THIN FILM FOR DEVELOPING AN ARRAY-LIKE PATTERN AND PROCESS FOR ITS PREPARATION

(71) Applicant: CHAIRMAN, DEFENCE RESEARCH AND DEVELOPMENT ORGANIZATION, New Delhi (IN)

(72) Inventors: Elangovan VARADARAJAN, Chennai (IN); Chandramohan MANIKANDAN, Chennai (IN); Mayakuthan KATHIRESAN, Avadi (Chennai) (IN); Venkatachalam NATARAJAN, Chennai (IN); Thankappan SANSTHANAKRISHAN, Kochi (IN)

(73) Assignee: CHAIRMAN, DEFENCE RESEARCH AND DEVELOPMENT ORGANIZATION, New Delhi (IN)

(21) Appl. No.: 19/138,755

(22) PCT Filed: Dec. 14, 2023
(86) PCT No.: PCT/IB2023/062672

§ 371 Date: Jun. 13, 2025

(30) Foreign Application Priority Data
Dec. 22, 2022 (IN) 202211074675

(51) Int. Cl. G03F 7/11; C09K 13/00; C23C 14/18; C23C 14/35; C23C 14/58; G03F 7/00; G03F 7/004; G03F 7/16; G03F 7/20; H10P 76/20

(52) U.S. Cl. CPC G03F 7/11; C09K 13/00; C23C 14/18; C23C 14/352; C23C 14/5806; G03F 7/0048; G03F 7/162; G03F 7/2002; G03F 7/70008; H10P 76/2041

(57) ABSTRACT

The present disclosure relates to a thin film for developing array-like pattern and a process for its preparation. The thin film of the present disclosure has strong adhesion, improved oxidation resistance, and etching compatibility with standard microfabrication techniques, and good electrical conductivity. Further, the thin film of the present disclosure is stable under oxygen and at high temperatures. Furthermore, the present disclosure also relates to a simple and economical process for preparing a thin film for developing array-like pattern.

### FIELD

The present disclosure relates to a thin film for developing an array-like pattern and a process for its preparation. Particularly, the present disclosure relates to a piezoelectric thin film for developing an array-like pattern and a process for its preparation.

### DEFINITIONS

As used in the present disclosure, the following terms are generally intended to have the meaning as set forth below, except to the extent that the context in which they are used indicates otherwise.

Lead (Pb) zirconate (Zr) titanate (Ti) (PZT): The Term ‘Lead (Pb) Zirconate (Zr) Titanate (Ti)’ refers to an inorganic compound with the chemical formula Pb[ZrₓTi₁₋ₓ]O₃ (05x≤1), commonly abbreviated as PZT, also called lead zirconium titanate. PZT is a ceramic perovskite material that shows a marked piezoelectric effect, wherein the compound changes shape when an electric field is applied. PZT is a solid solution of lead zirconate (PbZrO₃) and lead titanate (PbTiO₃) compounds, and has an ABO₃ perovskite crystalline structure, the same as the two compositional end members. It is used in several practical applications such as ultrasonic transducers and piezoelectric resonators. It is a white to off-white solid.

Microelectromechanical systems (MEMS): the term “MEMS” relates to micro mechatronics and microsystems constitute the technology of microscopic devices, particularly those with moving parts. They merge at the nanoscale into nanoelectromechanical systems (NEMS) and nanotechnology. MEMS are made up of components between 1 and 100 micrometers in size (i.e., 0.001 to 0.1 mm), and MEMS devices generally range in size from 20 micrometers to a millimeter (i.e., 0.02 to 1.0 mm), although components arranged in arrays (e.g., digital micromirror devices) can be more than 1000 mm². They usually consist of a central unit that processes data (an integrated circuit chip such as a microprocessor) and several components that interact with the surroundings (such as microsensors). Micro electromechanical systems (MEMS) is a process technology used to create tiny integrated devices or systems that combine mechanical and electrical components. MEMS refers to the fabrication of devices with at least some of their dimensions in the micrometer range. MEMS devices have the ability to sense, control and actuate on the microscale and generate effects on the macro scale.

Lift-off technique: Lift-off refers to the process of exposing a pattern into photoresist (or some other material), depositing a thin film (such as metal or dielectric) over the entire area. Then washing away the photoresist (or other material) to leave behind the film only in patterned area. Lift-off is a method of patterning a target material (typical a metal) using a sacrificial layer (typically photoresist) to define the pattern. Initially the sacrificial layer is applied and patterned optically. Then the target material is deposited on top. Finally, the resist will be dissolved and lifting away any metal that was on top of it and leaving the rest of the patterned metal on the substrate.

Microfabrication: The term “Microfabrication” or “MEMS fabrication” defines a series of techniques that can modify a substrate material in an additive or subtractive manner to convert a thin, generally planar, substrate into a complex structure of multiple materials through the interaction of microscopic features. Microfabrication is the process of fabricating miniature structures of micrometer scales and smaller.

Face-Centered Cubic (FCC): The term “Face-Centered Cubic” is the name given to a type of atom arrangement found in nature. A face-centered cubic unit (FCC) cell structure consists of atoms arranged in a cube where each corner of the cube has a fraction of an atom with six additional full atoms positioned at the center of each cube face.

Full Width at Half Maximum (FWHM): The term “Full Width at Half Maximum (FWHM)” is the difference between the two values of the independent variable at which the dependent variable is equal to half of its maximum value. In other words, it is the width of a spectrum curve measured between those points on the y-axis which are half the maximum amplitude. Half width at half maximum (HWHM) is half of the FWHM if the function is symmetric. The term full duration at half maximum (FDHM) is preferred when the independent variable is time.

### BACKGROUND

The background information herein below relates to the present disclosure but is not necessarily prior art.

Conventionally, lead (Pb) zirconate (Zr) titanate (Ti) (PZT) thin films are used in microelectromechanical (MEMS) systems. The performance of the PZT thin film based MEMS system are depending on two major factors such as integration of functional PZT layer onto traditional Si substrate and executing the complex patterning of multi-layered thin film by microfabrication techniques such as lithography, dry/wet etching, micromachining and the like. The incorporation of the PZT film into conventional Si substrate is a challenging task due to the incompatibility of the PZT film with the Si substrate. PZT reacts with Si substrate thereby leading to the formation of silicate phases at a temperature lower than 500 °C wherein generally PZT phase formation requires a temperature greater than 500 °C. In addition, a pore formation at the film/substrate interface of the PZT thin film causes deformation of the film surface thereby leading to an increase in roughness and degradation in the electrical properties of the film.

Generally, Pt has been primarily used as a bottom electrode because it does not react with PZT over the temperature range of interest for the processing of PZT thin films, but it cannot be directly used over the Si substrate because of its reactivity with Si at a temperature as low as 400 °C. Si reacts with Pt layer thereby leading to the formation of platinum silicide which is undesirable. The formation of platinum silicide also results in the diffusion of Pb from the top layer into the bottom Si substrates.

The patterning of platinum thin film is very sensitive to dry/wet etching techniques that could lead disadvantages such as to platinum surface contamination due to etching of the adhesion layer, low etch selectivity of platinum, delamination of platinum layer, and the like.

The patterning of platinum thin film heterostructure, before the piezo functional layer deposition, reduces the exposure of the piezo thin film layer from several microfabrication processes and prevents it from the structural damages induced during dry/wet etching of platinum. Conventionally, lift-off technique is used for applying a patterned thin film on a substrate surface. However, the lift-off technique is not an ideal process for the multi-layered platinized silicon thin film heterostructure, because the platinized silicon thin film heterostructure has to undergo high-temperature annealing treatment after the Pt/Ti deposition to attain the stable bottom electrode configuration. Since the lift-off technique may introduce the risk of particle formation and very often has poorly defined Pt edges after the etching. So it is required to develop an alternative microfabrication process to pattern the metal platinum layer.

There is, therefore, felt a need to provide a thin film for developing an array-like pattern and a process for its preparation that mitigates the drawbacks mentioned hereinabove or at least provide a useful alternative.

### OBJECTS

Some of the objects of the present disclosure, which at least one embodiment herein satisfies, are as follows:
An object of the present disclosure is to ameliorate one or more problems of the background or to at least provide a useful alternative.
Another object of the present disclosure is to provide a thin film for developing an array-like pattern.
Still another object of the present disclosure is to provide a thin film for developing an array-like pattern that has strong adhesion, improved oxidation resistance, and etching compatibility with standard microfabrication techniques and good electrical conductivity.
Another object of the present disclosure is to provide a thin film for developing an array-like pattern that exhibits denser uniform grain growth without cracks.
Yet another object of the present disclosure is to provide a thin film for developing an array-like pattern that is stable under oxygen and high temperature.
Another object of the present disclosure is to provide a thin film for developing an array-like pattern that can be patterned with an array-like structure by a wet etching process.
Still another object of the present disclosure is to provide a process for preparing a thin film for developing an array-like pattern that is simple and economical.
Another object of the present disclosure is to provide a process for developing an array like pattern on a thin film.

Other objects and advantages of the present disclosure will be more apparent from the following description, which is not intended to limit the scope of the present disclosure.

### SUMMARY

The present disclosure relates to a thin film for developing an array-like pattern. The thin film comprises at least one layer of at least one substrate, at least one layer of at least one insulating material, at least one layer of at least one transition metal oxide, and at least one layer of at least one metal. The transition metal oxide layer is sandwiched between the insulating material layer and the metal layer

The present disclosure also relates to a process for the preparation of a thin film for developing an array-like pattern. The process comprises the step of obtaining a substrate having a predetermined thickness. The substrate is cleaned to obtain a cleaned substrate. At least one layer of at least one insulating material is deposited on a top operative surface of the cleaned substrate by thermal oxidation at a first predetermined temperature for a first predetermined time period to obtain a reaction barrier layer of the substrate and the insulating material. At least one layer of at least one transition metal is deposited on a top operative surface of the reaction barrier layer in an inert atmosphere at a second predetermined temperature for a second predetermined time period at a first predetermined deposition rate to obtain an adhesion layer. At least one layer of at least one metal is deposited on a top operative surface of the adhesion barrier layer in an inert atmosphere at a third predetermined temperature for a third predetermined time period at a second predetermined deposition rate to obtain a film. The film is annealed under an inert-oxygen atmosphere at a temperature in the range of 600 °C to 800 °C at a heating rate in the range of 0.4 °C/s to 1 °C/s for a time period in the range of 20 minutes to 60 minutes to obtain an annealed film. The so obtained annealed film is maintained for a time period in the range of 20 minutes to 60 minutes, followed by cooling to a temperature in the range of 250 °C to 300 °C, followed by further cooling to a temperature in the range of 20 °C to 40 °C to obtain the thin film.

### BRIEF DESCRIPTION OF THE ACCOMPANYING DRAWING

The present disclosure will now be described with the help of the accompanying drawing, in which:

FIG. 1 illustrates a working pressure characteristics of Pt/Ti deposition by DC magnetron sputtering process, in accordance with the present disclosure;

FIG. 2 illustrates a temperature profile adapted for the thin film by annealing, in accordance with the present disclosure;

FIG. 3 represents a schematic diagram of an array of micro fabricated large area of the thin film, in accordance with the present disclosure;

FIG. 4 (a) depicts an X-ray diffraction characteristics of the thin film, in accordance with the present disclosure;

FIG. 4 b depicts an X-ray diffraction mapping across the thin film, in accordance with the present disclosure;

FIG. 5 depicts an electrical resistivity mapping across the thin film, in accordance with the present disclosure;

FIG. 6 (a) depicts the cross-sectional Field emission electron microscopic (FESEM) images of the thin film, in accordance with the present disclosure;

FIG. 6 (b) depicts Planar Field emission electron microscopic (FESEM) images of the thin film, in accordance with the present disclosure;

FIG. 7 (a) depicts the Topographical (3-D) Atomic force microscopic images of the thin film, in accordance with the present disclosure; and

FIG. 7 (b) depicts Planar (2-D) Atomic force microscopic images of the thin film, in accordance with the present disclosure.

### DETAILED DESCRIPTION

Embodiments of the present disclosure will now be described with reference to the accompanying drawing.

Embodiments are provided so as to thoroughly and fully convey the scope of the present disclosure to the person skilled in the art. Numerous details are set forth, relating to specific components, and methods, to provide a complete understanding of embodiments of the present disclosure. It will be apparent to the person skilled in the art that the details provided in the embodiments should not be construed to limit the scope of the present disclosure. In some embodiments, well-known processes, well-known apparatus structures, and well-known techniques are not described in detail.

The terminology used, in the present disclosure, is only for the purpose of explaining a particular embodiment and such terminology shall not be considered to limit the scope of the present disclosure. As used in the present disclosure, the forms “a,” “an,” and “the” may be intended to include the plural forms as well, unless the context clearly suggests otherwise. The terms “comprises,” “comprising,” “including,” and “having,” are open ended transitional phrases and therefore specify the presence of stated features, integers, steps, operations, elements, modules, units and/or components, but do not forbid the presence or addition of one or more other features, integers, steps, operations, elements, components, and/or groups thereof. The particular order of steps disclosed in the method and process of the present disclosure is not to be construed as necessarily requiring their performance as described or illustrated. It is also to be understood that additional or alternative steps may be employed.

As used herein, the term “and/or” includes any and all combinations of one or more of the associated listed elements.

The terms first, second, third, etc., should not be construed to limit the scope of the present disclosure as the aforementioned terms may be only used to distinguish one element, component, region, layer or section from another component, region, layer or section. Terms such as first, second, third etc., when used herein do not imply a specific sequence or order unless clearly suggested by the present disclosure.

The patterning of platinum thin film heterostructure is very sensitive to dry/wet etching techniques that could lead to platinum surface contamination due to etching of the adhesion layer, low etch selectivity of platinum, delamination of platinum layer, and the like.

The patterning of platinum thin film heterostructure, before the piezo functional layer deposition, reduces the exposure of the piezo thin film layer from several microfabrication processes and prevents it from the structural damages induced during dry/wet etching of platinum. However, the lift-off technique is not an ideal process for the multi-layered platinized silicon thin film heterostructure, because the platinized silicon thin film heterostructure has to undergo high-temperature annealing treatment after the Pt/Ti deposition to attain the stable bottom electrode configuration. Since the lift-off technique may introduce the risk of particle formation and very often has poorly defined Pt edges after the etching. So it is required to develop an alternative microfabrication process to pattern the metal platinum layer.

The present disclosure relates to a thin film for developing an array-like pattern and a process for its preparation. Particularly, the present disclosure relates to a piezoelectric thin film for developing an array-like patter and a process for its preparation In an aspect, the present disclosure provides a thin film for developing an array-like pattern. The thin film comprises at least one layer of at least one substrate, at least one layer of at least one insulating material, at least one layer of at least one transition metal oxide, and at least one layer of at least one metal. The transition metal oxide layer is sandwiched between the insulating material layer and the metal layer.

In accordance with an embodiment of the present disclosure, the substrate is selected from the group consisting of silicon, sapphire (Al₂O₃), magnesium oxide (MgO), gallium nitride (GaN), and silicon carbide (SIC). In an exemplary embodiment, the substrate is silicon.

In accordance with an embodiment of the present disclosure, the substrate layer has a thickness in the range of 200 μm to 400 μm. In an exemplary embodiment, the substrate layer has a thickness of 300 μm.

In accordance with an embodiment of the present disclosure, the insulating material is selected from the group consisting of silicon dioxide (SiO₂), silicon nitride (SiN). In an exemplary embodiment, the insulating material is silicon dioxide (SiO₂).

In accordance with an embodiment of the present disclosure, the insulating material layer has a thickness in the range of 500 nm to 600 nm. In an exemplary embodiment, the insulating material layer has a thickness of 550 nm.

In accordance with an embodiment of the present disclosure, the transition metal oxide is at least one selected from the group consisting of titanium dioxide and zirconium oxide. In an exemplary embodiment, the transition metal oxide is titanium dioxide.

In accordance with an embodiment of the present disclosure, the transition metal oxide layer has a thickness in the range of 30 nm to 100 nm. In an exemplary embodiment, the transition metal oxide layer has a thickness of 50 nm.

In accordance with an embodiment of the present disclosure, the metal of the metal layer is at least one selected from the group consisting of platinum, iridium, ruthenium, and copper. In an exemplary embodiment, the metal of the metal layer is platinum (Pt).

In accordance with an embodiment of the present disclosure, the metal layer has a thickness in the range of 200 nm to 300 nm. In an exemplary embodiment, the metal layer has a thickness of 250 nm.

In accordance with an embodiment of the present disclosure, a ratio of a thickness of the metal layer to the transition metal oxide layer is in the range of 2:1 to 10:1. In an exemplary embodiment, a ratio of a thickness of the metal layer to the transition metal oxide layer is 5:1.

In accordance with an embodiment of the present disclosure, the thin film has a thickness in the range of 200 μm to 500 μm. In an exemplary embodiment, the thin film has a thickness of 380 μm.

In accordance with an embodiment of the present disclosure, the thin film is characterized by having:
an electrical resistivity in the range of 10 μΩ-cm to 15 μΩ-cm;
a full width half maxima (FWHM) in the range of 0.1 to 0.5; and
a root mean square roughness in the range of 2 nm to 8 nm.

In another aspect, the present disclosure provides a process for the preparation of a thin film for developing an array-like pattern. The process comprises the following steps:
In a first step of preparing the thin film, a substrate having a predetermined thickness is obtained.

In accordance with an embodiment of the present disclosure, the substrate is selected from the group consisting of silicon, silicon, sapphire (Al₂O₃), magnesium oxide (MgO), gallium nitride (GaN), and silicon carbide (SIC). In an exemplary embodiment, the substrate is silicon.
In a second step of preparing the thin film, the substrate is cleaned to obtain a cleaned substrate.

The cleaning is done by heating the substrate with organic solvents to remove the impurities. To synthesize high-purity thin films, it is necessary to have a clean substrate surface. The purpose of substrate cleaning is to remove the chemical impurities, and particles present on the surface of the substrate without altering or damage to its surface. Substrate (Si wafer) may include contaminants on the surface like skin oils, dirt grease, and the like because the substrate preparation process also has high electro negativity of about 1.8 eV that is prone to have metal contaminants on its surface.
In a third step of preparing the thin film, at least one layer of at least one insulating material is deposited on a top operative surface of the cleaned substrate by thermal oxidation at a first predetermined temperature for a first predetermined time period to obtain a reaction barrier layer of the substrate and the insulating material.

A three step dry-wet-dry thermal oxidation process is applied to grow the insulating material over the substrate in high-temperature furnace.

In accordance with an embodiment of the present disclosure, the insulating material is selected from the group consisting of silicon dioxide (SiO₂) and silicon nitride (SiN). In an exemplary embodiment, the insulating material is silicon dioxide (SiO₂).

In accordance with an embodiment of the present disclosure, the first predetermined temperature is in the range of 900 °C to 1200 °C. In an exemplary embodiment, the first predetermined temperature is 1050 °C

In accordance with an embodiment of the present disclosure, the first predetermined time period is in the range of 60 minutes to 180 minutes. In an exemplary embodiment, the first predetermined time period is 100 minutes.
In a fourth step of preparing the thin film, at least one layer of at least one transition metal is deposited on a top operative surface of the reaction barrier layer in an inert atmosphere at a second predetermined temperature for a second predetermined time period at a first predetermined deposition rate to obtain an adhesion layer of the substrate, the insulating material and the transition metal oxide.

In accordance with an embodiment of the present disclosure, the transition metal is at least one selected from the group consisting of titanium and zirconium. In an exemplary embodiment, the transition metal is titanium.

In accordance with an embodiment of the present disclosure, the second predetermined temperature is in the range of 20 °C to 40 °C. In an exemplary embodiment, the second predetermined temperature is 25 °C.

In accordance with an embodiment of the present disclosure, the second predetermined time period is in the range of 2 minutes to 15 minutes. In an exemplary embodiment, the second predetermined time period is 5 minutes.

In accordance with an embodiment of the present disclosure, the first predetermined deposition rate is in the range of 5 nm/minute to 15 nm/minute. In an exemplary embodiment, the second predetermined deposition rate is 10 nm/minute.
In a fifth step of preparing the thin film, at least one layer of at least one metal is deposited on a top operative surface of the adhesion barrier layer in an inert atmosphere at a third predetermined temperature for a third predetermined time period at a second predetermined deposition rate to obtain a film.

In accordance with an embodiment of the present disclosure, the second predetermined deposition rate is in the range of 5 nm/minute to 15 nm/minute. In an exemplary embodiment, the second predetermined deposition rate is 10 nm/minute.

In accordance with an embodiment of the present disclosure, the metal of the metal layer is at least one selected from the group consisting of platinum, iridium, ruthenium, and copper. In an exemplary embodiment, the metal of the metal layer is platinum (Pt).

In accordance with an embodiment of the present disclosure, the third predetermined temperature is in the range of 20 °C to 40 °C. In an exemplary embodiment, the third predetermined temperature is 25 °C.

In accordance with an embodiment of the present disclosure, the third predetermined time period is in the range of 2 minutes to 15 minutes. In an exemplary embodiment, the third predetermined time period is 5 minutes.
In a sixth step of preparing the thin film, the film is annealed under an inert-oxygen atmosphere at a temperature in the range of 600 °C to 800 °C at a heating rate in the range of 0.4 °C/s to 1 °C/s for a time period in the range of 20 minutes to 60 minutes to obtain an annealed film.

The annealing process converts transition metal to transition metal oxide to control the Ti diffusion to the top metal layer and to crystallize the top Pt metal layer along the orientation in the closely packed FCC structure.

Ar/O₂ mixed gas atmosphere is used for annealing because the Ti has high diffusion characteristics at high temperatures. Annealing solely in the inert atmosphere makes Ti to diffuse through the top Pt layer where it will affect the interface between Pt and the subsequent deposition layer. Whereas annealing only at O₂ atmosphere stops the diffusion of Ti on the top layer by the formation of an oxide with Ti. Since Ti has multiple oxidation states. It is difficult to know its oxide form and it can form different titanium oxides (TiOₓ₋) through the layer inside Ti and Pt. To overcome the above issues, a mixture of Ar gas and O₂ atmosphere is used and Ar is taken at a higher ratio than Ti because the low oxygen content makes the Ti to form its oxide only in the Ti layer but not inside the Pt layer.

In accordance with an embodiment of the present disclosure, the inert atmosphere is at least one selected from the group consisting of argon, helium, and neon. In an exemplary embodiment, the inert atmosphere is argon.
In a seventh step of preparing the thin film, the annealed film is maintained a time period in the range of 20 minutes to 60 minutes, followed by cooling to a temperature in the range of 250 °C to 300 °C, followed by further cooling to a temperature in the range of 20 °C to 40 °C to obtain the thin film.

The thin film of the present disclosure exhibits unique physical properties such as strong adhesion, oxidation resistance, etching compatibility with standard microfabrication techniques, good electrical conductivity and the like. Further, the thin film of the present disclosure has clear interface between each underlying layer, ideal thickness of each layer, stability under oxygen, high temperature treatment and ability to pattern the large area into array like structure by wet etching technique.

The thin film of the present disclosure is used for manufacturing underwater hydrophones, pressure sensors, accelerometers, energy harvesters, other piezoelectric based MEMS devices and the like.

In another aspect, the present disclosure provides a process for developing an array-like pattern on a thin film. The process is explained in detail as follows:

In a first step of developing an array-like pattern on a thin film, a top layer of transition metal oxide and metal of the thin film is cleaned and followed by heating at a temperature in the range of 110 °C to 150 °C for a time period in the range of 3 minutes to 5 minutes to obtain a cleaned thin film.

To develop a well defined array like pattern, it is necessary to have a clean top layer. It removes the chemical impurities and particles present on the surface which is required for the good adhesion of top layer.

In a second step of developing an array-like pattern on a thin film, a layer of photoresist material is coated on the cleaned thin film by using a spin coating process at a spinning speed in the range of 3000 rpm to 5000 rpm for a time period in the range of 10 seconds to 50 seconds to obtain a photoresist material coated thin film.

In accordance with an embodiment of the present disclosure, the photoresist material is methoxy-1-methyl ethyl acetate (AZ 4000 series).

In accordance with an embodiment of the present disclosure, the photoresist material has a thickness in the range of 3 μm to 10 μm.

In a third step of developing an array-like pattern on a thin film, UV light having a wavelength in the range of 300 nm to 500 nm is irradiated though a photomask on the photoresist material coated thin film to obtain an UV irradiated thin film.

In a fourth step of developing an array-like pattern on a thin film, UV irradiated thin film is washed with a developer solution for a time period in the range of 60 seconds to 90 seconds to remove soluble photoresist material, followed by baking at a temperature in the range of 110 °C to 130 °C for a time period in the range of 30 seconds to 120 seconds, followed by further baking at a temperature in the range of 110 °C to 130 °C for a time period in the range of 10 minutes to 15 minutes to obtain an array like developed thin film.

In accordance with an embodiment of the present disclosure, the developer solution (MF 20A series) comprises:
water in an amount in the range of 97.5 mass % to 98 mass % with respect to the total amount of the solution;
tetramethylammonium hydroxide (TMAH) in an amount in the range of 1.9 mass % to 2.45 mass % with respect to the total amount of the solution; and
polyglycol in an amount in the range of 0.05 mass % to 0.1 mass % with respect to the total amount of the solution.

In accordance an exemplary embodiment, the developer solution (MF 20A series) comprises: water in an amount of 97.5 mass % with respect to the total amount of the solution, tetramethylammonium hydroxide (TMAH) in an amount of 2.45 mass % with respect to the total amount of the solution and polyglycol in an amount of 0.05 mass % with respect to the total amount of the solution.

In a fifth step of developing an array-like pattern on a thin film, the array like pattern developed thin film is etched by dissolving it in a mixture of HNO₃: HCl: H2O solution having a molar ratio of 7:1:8 at a temperature in the range of 60 °C to 80 °C to obtain the array of thin film.

The foregoing description of the embodiments has been provided for purposes of illustration and is not intended to limit the scope of the present disclosure. Individual components of a particular embodiment are generally not limited to that particular embodiment, but, are interchangeable. Such variations are not to be regarded as a departure from the present disclosure, and all such modifications are considered to be within the scope of the present disclosure.

The present disclosure is further described in light of the following experiments which are set forth for illustration purpose only and not to be construed for limiting the scope of the disclosure. The following experiments can be scaled up to industrial/commercial scale and the results obtained can be extrapolated to industrial scale.

### EXPERIMENTAL DETAILS

### Experiment 1: Process for the Preparation of a Thin Film for Developing an Array-Like Pattern, in Accordance with the Present Disclosure

### Preparation of a Cleaned Substrate:

Initially the silicon wafer (substrate) was heated with trichloro-ethylene (TCE) at 80 °C for 5 minutes to remove the grease on the surface while used for dicing the Si-Wafer. After heating with TCE, two-step cleaning process was done using acetone and isopropyl alcohol. Si wafer was heated with acetone at 80 °C for 5 minutes. Acetone has the property of leaving its residue on the Si wafer (substrate) surface, hence the Si wafer was immediately rinsed with isopropyl alcohol. Isopropyl alcohol stops the streak formation caused by acetone. Further, Si wafer (substrate) was rinsed with deionized (DI) water. Clean DI water destroys the effect of organic solvent cleaning; hence DI water with 18 MΩ resistivity was used.

Immediately after cleaning, silicon oxide was intentionally formed on the Si surface by subjecting it to the nitric acid (HNO₃) and etching at 120 °C for 5 to 10 min. Silicon oxide was purposely formed on the surface to have a new surface followed by a hydrofluoric acid dip. The silicon oxide layer was removed by dipping the wafer in the mixture of H₂O: HF solution having a ratio of 100:1 for 1 minute at room temperature. H₂O: HF solution ratio was chosen to have the control in removal rate of SiO₂ layer to avoid deep etching in the Si wafer. Then, Si wafer (substrate) was rinsed with DI water at room temperature. After that Si wafer (substrate) was dried with nitrogen (N₂) gas. In the process of rinsing in DI water and exposure to air, the substrate adsorbs the water molecules on its surface. To remove the water molecules from the surface, the substrate was heated at 140 °C for a few minutes to obtain a cleaned Si wafer (substrate). The heating above 140 °C removes the OH bonds on the surfaces exposed to air humidity and improves the adhesion during the coating.

### Preparation of a Reaction Barrier Layer of the Substrate and the Insulating Material:

The insulating material layer was deposited on the cleaned Si wafer (substrate) by thermal oxidation process in a high-temperature furnace at 1050 °C for a period of 100 minutes.

SiO₂ was deposited over Si wafer through three-step process i.e. dry-wet-dry oxide deposition. The cleaned Si wafer was placed inside a furnace in the constant temperature zone maintained at 1050 °C. To avoid the sudden thermal shock, the cleaned Si wafer was moved slowly inside the furnace. SiO₂ of 15 nm was initially deposited through a wet oxidation process to have a good interface between cleaned Si wafer and SiO₂ layer. In the dry oxidation process, O₂ of about 30 standard cubic centimeters (SCCM) was allowed to flow inside the furnace where the rate of deposition was 2.5 nm/min to obtain a dry oxide layer.

Subsequently, wet oxide of SiO₂ of 500 nm was deposited over the dry oxide layer where the pure oxygen gas was mixed with O₂ gas that is separated from H₂O through bubbler of ratio 3:1. The rate of deposition was 6 nm/min which was higher than dry oxidation process. The wet oxidation layer was trailed by the dry oxide layer to have good interface at the top layer. A dry oxide layer of thickness 25 nm is deposited for 10 min to obtain a reaction barrier layer of substrate (Si wafer) and insulating material (silicon dioxide).

### Preparation of an Adhesion Layer of the Substrate, the Insulating Material, and the Transition Metal Oxide and Preparation of a Film

The transition metal layer deposition was carried out by using DC magnetron sputtering process.

The reaction barrier layer of the substrate (Si wafer) and the insulating material (silicon dioxide) was mounted on the 4-inch substrate holder which was placed inside the sputtering chamber. Ti (transition metal) and Pt (metal) circular target (99.99 % purity) of 50.8 mm diameter with 1.6 mm thickness were mounted on the two cylindrical magnetrons facing opposite to each other with an off-axis angle 15°. Before deposition of Ti and Pt, targets were cleaned with an isopropanol solution to remove the contaminants.

The source to substrate distance was kept constant for both Pt and Ti depositions of about 15 cm. Sputter growth was carried out in an argon (Ar) gas (inert) atmosphere. Ar gas acts as a carrier gas that will ionize into Ar⁺by secondary electrons which eject the target atoms toward the substrate. For the ignition of plasma Ar pressure of 40×10⁻³ mbar with DC power 85 W was applied and high pressure of Ar gas was passed for the self-sustainable plasma.

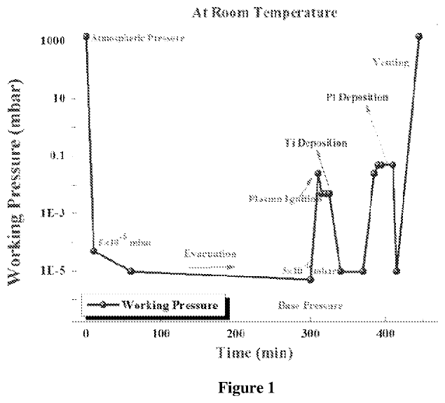

The plasma power used for Pt and Ti deposition was 200 W. The substrate rotation was maintained throughout the deposition to maintain the uniform thickness across the wafer with a substrate rotation of 5 rpm. Both Ti and Pt deposition was done at room temperature. The working pressure characteristics of Ti and Pt deposition was displayed in FIG. 1. After reaching the base pressure of 5×10⁻⁶ mbar, Ar gas was passed inside the chamber for plasma ignition where the pressure reaches about 2.5×10⁻² mbar. For deposition, the pressure was again reduced to 10×10⁻³ mbar and 10×10⁻³ mbar for Pt and Ti deposition respectively. Ti was deposited over SiO₂ wafer to obtain an adhesion layer of substrate (Si), insulating material (SiO₂), and transition metal (Ti) followed by Pt deposition without breaking the vacuum to obtain a film. Ti was deposited at a rate of about 10 nm/min for 5 minutes to obtain a thickness of 35 nm and the Pt was deposited for 5 minutes duration to obtain a thickness of 250 nm respectively. After Pt deposition, samples were annealed in both in-situ and ex-situ conditions. One of the samples were annealed immediately after Pt deposition in the sputtering chamber without breaking the vacuum.

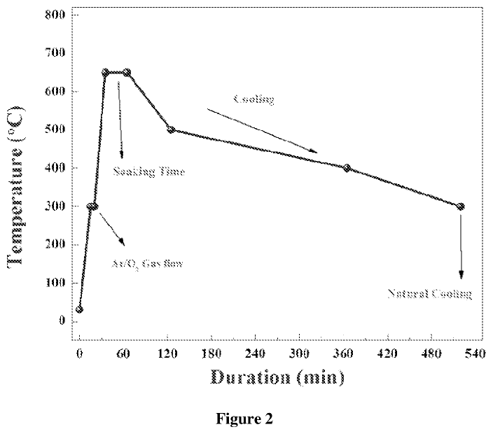

The annealing of the film was carried out by using a high-temperature three-zone tubular furnace (M/s. Ants ceramics, India.). The annealing of the film was performed in the mixed inert Argon gas and reactive Oxygen atmosphere. The temperature of the tubular furnace was raised from room temperature to 650 °C at the heating rate of 0.8 °C/s to convert the Ti layer into the TiO₂ layer. Then, the film dwelled at an annealing temperature for 30 minutes. After dwelling, the film was cooled down to 300 °C for 30 minutes and allowed to cool naturally to room temperature as shown in FIG. 2. After cooling, the thin film was obtained.

### Experiment 2: A Process for Developing an Array-Like Pattern on Thin Film, in Accordance with the Present Disclosure

The array of box-like structures was patterned by an optical lithographic process. 4-inch chromium coated glass mask was used where an array of box-like pattern was written using mask writer (DWL 66 Heidelberg Instruments GmbH, Germany). The photoresist material of 2-methoxy-1-methyl ethyl acetate (AZ series 4562) was coated on the top Pt/TiO₂ layer by using a spin coater where the spin speed of 4000 rpm for 40 seconds was applied to obtain the resist of thickness 6 μm. Before photoresist coating, the top Pt/TiO₂ layer was subjected to the conventional organic cleaning followed by heating at 110 °C to 150 °C for 3 minutes to 5 minutes. The photoresist material was selected in such a way that it should provide a barrier to Pt/TiO₂ etching in the patterned area and good selectivity in the wet etching process. After bringing the mask parallel to the top Pt/TiO₂ layer, it was exposed to UV (Ultra Violet) light of wavelength 365 nm. The power used for the UV exposure was 500 W for the exposure energy 18 mJ/cm² and the period of UV exposure was 10 seconds to 13 seconds. Then, it was developed using MF26A developer solution consisting 97.5 mass % of water and 2.45 mass % of tetramethylammonium hydroxide (TMAH) and 0.05 mass % of polyglycol for 60 seconds to 90 seconds and soft baked at 110 °C to 130 °C for 1 min. The developed patterns were confirmed by optical microscope and further hard baked at 110 °C to 130 °C for 10 minutes to 15 minutes.

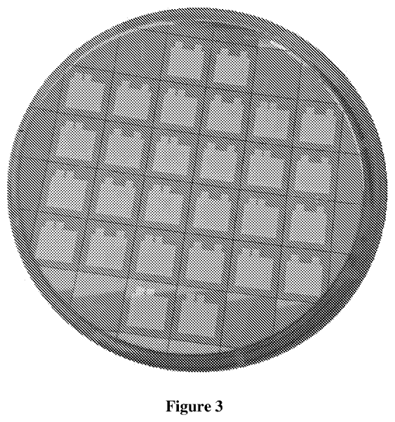

The thin film with lithographic patterns was immersed in aqua regia for the Pt wet etching. The aqua regia is a mixture of nitric acid and hydrochloric acid, that can etch noble metals which were chosen for Pt etching because the intrinsic inert nature of platinum limits its etching against most solvents. A freshly aqua regia mixture of a ratio of 7:1:8(HNO₃:HCl:H₂O) was used for the reproducible etching results. The constituents of aqua regia were chosen to help in controlling the etch rate. The Pt top layer was etched at a temperature of 70 °C for 5 minutes which results in uniform, well-defined Pt edges. Then, the TiO₂ layer was etched in the mixture of ammonium hydroxide (NH₄OH, 26%) and hydrogen peroxide (H₂O₂, 30 %) solution at 70 °C for a period of 60 seconds to 90 seconds. After the etching of Pt/TiO₂ layer, the remaining photoresist material was removed by dissolving it into acetone. After dissolving, uniform and well-defined etch patterns were observed in the optical microscope. FIG. 3 represents the schematic diagram of an array developed on the thin film.

### Experiment 3: Characterization of The Array-Like Pattern Developed on the Thin Film Obtained in Experiment 2 of the Present Disclosure

### X-Ray Diffraction

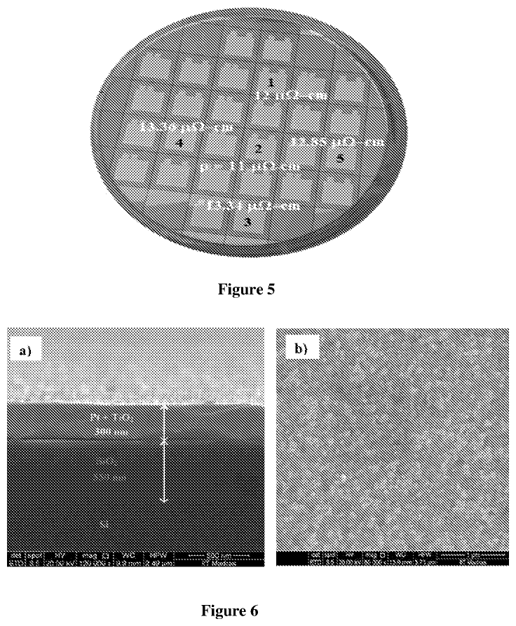

The array-like pattern developed on the thin film obtained in experiment 2 was investigated by Rigaku glancing incidence X-ray diffraction (GIXRD) using CuKα radiation ( λ=0.15418 nm), which was operated at 40 kV and 30mA with grazing angle of 1°. All the XRD patterns were recorded at θ-2θ mode in the range of 20° to 70° and at the scan speed of 2°/min with the step size of 0.01°. XRD patterns were analyzed using X'Pert High Score Plus software and compared with Joint Committee on Powder Diffraction Standards (JCPDS) data. X-ray diffraction patterns of ex situ annealed Pt/Ti films were recorded on the five different places across the wafer was displayed in the FIG. 5.

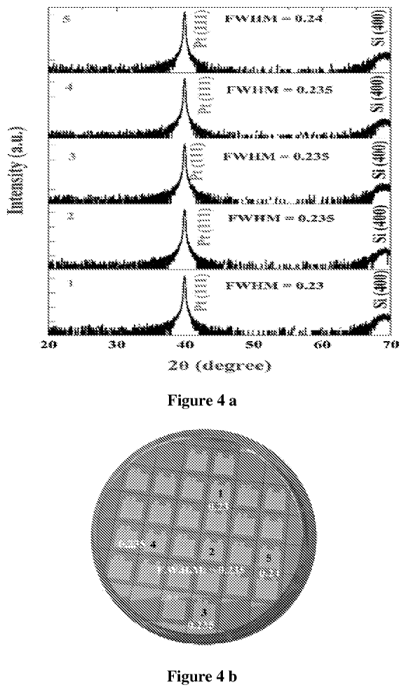

FIG. 4a depicts an X-ray diffraction characteristics of an array-like pattern developed on the thin film and FIG. 4b depicts an X-ray diffraction mapping across an array-like pattern developed on the thin film.

From the XRD patterns, it is inferred that the Pt films which were annealed showed the highly intense Pt peak at 2θ=39.76° for all different spots across the wafer and there were no impurity peaks observed. In X-ray diffraction pattern, only an oriented Pt peak was observed and the absence of other crystallographic planes belonging to Pt suggests that the Pt was crystallized in face-centered cubic (FCC) structure. The full width half maximum (FWHM) of Pt peaks was calculated from the XRD pattern which is in the range of 0.25 to 0.27 revealing that the Pt films are well crystallized. The full width half maximum values are the same at all diffraction spots showed the Pt films crystallized with high quality and uniformity across the wafer.

### Surface Morphology: Field Emission Scanning Electron Microscopy (FE-SEM)

The surface morphology of an array-like pattern developed on the thin film was analyzed using SUPRA-55 Carl Zeiss Field Emission Scanning Electron Microscopy (FE-SEM). The surface topography, average (Ra), and root mean square (RMS) surface roughness of the films were measured by atomic force microscope (Bruker, Dimension Edge, USA) in the tapping mode.

FIG. 6 (a) depicts the cross-sectional Field emission electron microscopic (FESEM) images of the thin film and FIG. 6 (b) depicts Planar Field emission electron microscopic (FESEM) images of the thin film, in accordance with the present disclosure. From FIG. 6 (a-b), it is evident that the cross-sectional view showed the thickness of each layer with TiO₂ of thickness 40 nm and the Pt of thickness 200 nm respectively. The array-like pattern developed on the thin film are denser along the thickness mode direction with a columnar grain structure. The cross-sectional FESEM micrographs of the array-like pattern developed on the thin film showed a clear interface between each layer. In planar view, the surface of the array-like pattern developed on the thin film exhibited denser grain growth perpendicular to the film surface. This type of growth mode is expected as the XRD patterns indicated a predominantly oriented along the crystal direction.

### Electrical Resistivity

The electrical resistivity of platinized silicon films was measured by using the four probe resistive method at room temperature. Resistivity was measured at five different spots across the wafer and similar properties were exhibited for all the spots as shown in FIG. 6. The electrical resistivity of platinized silicon films annealed in in-situ and ex-situ environments has a value in the range of 11-13 μΩ-cm and exhibited almost uniform electrical resistivity across the wafer. In general, Pt films have a resistivity below 50 μΩ-cm and both the differently annealed platinized silicon thin films have electrical resistivity well below 50 μΩ-cm.

### Atomic Force Microscopic (AFM)

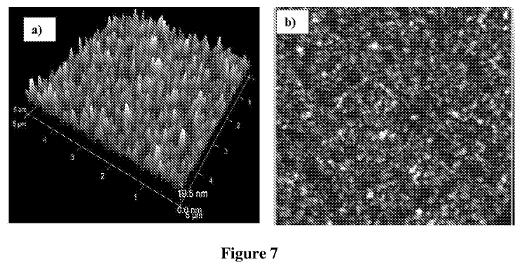

The surface topography and the surface roughness of the array-like pattern developed on the thin film were analyzed by Atomic force microscopic (AFM) in non-contact tapping mode. The surface roughness was scanned over the area of 5 μm×5 μm on the surface of the coating and the morphologies are shown in FIG. 7. FIG. 7 (a) depicts the Topographical (3-D) Atomic force microscopic images of the thin film and FIG. 7 (b) depicts Planar (2-D) Atomic force microscopic images of the thin film, in accordance with the present disclosure.

The surface morphology of the thin film showed that smooth and denser surface with a root mean square roughness of 4.84 nm whereas the mean roughness is 3.85 nm. From AFM micrographs, it is seen that the film was crystallized without crack and distributed uniformly.

### TECHNICAL ADVANCEMENTS

The present disclosure described herein above has several technical advantages including, but not limited to, the realization of a thin film for developing array-like pattern that:
exhibits strong adhesion, oxidation resistance, etching compatibility with standard microfabrication techniques, and good electrical conductivity;
exhibits denser uniform grain growth without crack;
is stable under oxygen and high temperature; and
can be patterned with an array-like structure by wet etching process; and
   a process for preparing the thin film for developing array-like pattern that:
is simple and economical.

Throughout this specification the word “comprise”, or variations such as “comprises” or “comprising, will be understood to imply the inclusion of a stated element, integer or step,” or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the invention to achieve one or more of the desired objects or results. While certain embodiments of the inventions have been described, these embodiments have been presented by way of example only, and are not intended to limit the scope of the inventions. Variations or modifications to the formulation of this invention, within the scope of the invention, may occur to those skilled in the art upon reviewing the disclosure herein. Such variations or modifications are well within the spirit of this invention.

The numerical values given for various physical parameters, dimensions and quantities are only approximate values and it is envisaged that the values higher than the numerical value assigned to the physical parameters, dimensions and quantities fall within the scope of the invention unless there is a statement in the specification to the contrary.

While considerable emphasis has been placed herein on the specific features of the preferred embodiment, it will be appreciated that many additional features can be added and that many changes can be made in the preferred embodiment without departing from the principles of the disclosure. These and other changes in the preferred embodiment of the disclosure will be apparent to those skilled in the art from the disclosure herein, whereby it is to be distinctly understood that the foregoing descriptive matter is to be interpreted merely as illustrative of the disclosure and not as a limitation.

The economy significance details requirement may be called during the examination. Only after filing of this Patent application, the applicant can work publically related to present disclosure product/process/method. The applicant will disclose all the details related to the economic significance contribution after the protection of invention.

1. A thin film for developing an array-like pattern comprising:
at least one layer of at least one substrate;
at least one layer of at least one insulating material;
at least one layer of at least one transition metal oxide; and
at least one layer of at least one metal;
wherein said transition metal oxide layer is sandwiched between said insulating material layer and said metal layer.

2. The thin film as claimed in claim 1, wherein said substrate is selected from the group consisting of silicon, silicon, sapphire (Al₂O₃), magnesium oxide (MgO), gallium nitride (GaN), and silicon carbide (SIC).

3. (canceled)

4. The thin film as claimed in claim 1, wherein said insulating material is selected from the group consisting of silicon dioxide (SiO₂) and silicon nitride (SiN).

5. (canceled)

6. The thin film as claimed in claim 1, wherein said transition metal oxide is at least one selected from the group consisting of titanium dioxide and zirconium oxide.

7. (canceled)

8. The thin film as claimed in claim 1, wherein said metal of said metal layer is at least one selected from the group consisting of platinum (Pt), iridium, ruthenium, and copper.

9. The thin film as claimed in claim 1, wherein
said substrate layer has a thickness in the range of 200 μm to 400 μm;
said insulating material layer has a thickness in the range of 500 nm to 600 nm;
said transition metal oxide layer has a thickness in the range of 30 nm to 100 nm; and
said metal layer has a thickness in the range of 200 nm to 300 nm.

10. The thin film as claimed in claim 1, wherein said thin film has a thickness in the range of 200 μm to 500 μm.

11. The thin film as claimed in claim 1 is characterized by having:
an electrical resistivity in the range of 10 μΩ-cm to 15 μΩ-cm;
a full width half maxima (FWHM) in the range of 0.1 to 0.5; and
a root mean square roughness in the range of 2 nm to 8 nm.

12. A process for the preparation of a thin film for developing an array-like pattern, wherein said process comprising the following steps:
a. obtaining a substrate having a predetermined thickness;
b. cleaning said substrate to obtain a cleaned substrate;
c. depositing at least one layer of at least one insulating material on a top operative surface of said cleaned substrate by thermal oxidation at a first predetermined temperature for a first predetermined time period to obtain a reaction barrier layer of said substrate and said insulating material;
d. depositing at least one layer of at least one transition metal on a top operative surface of said reaction barrier layer in an inert atmosphere at a second predetermined temperature for a second predetermined time period at a first predetermined deposition rate to obtain an adhesion layer of said substrate, said insulating material and said transition metal oxide;
e. depositing at least one layer of at least one metal on a top operative surface of said adhesion barrier layer in an inert atmosphere at a third predetermined temperature for a third predetermined time period at a second predetermined deposition rate to obtain a film;
f. annealing said film under inert-oxygen atmosphere at a temperature in the range of 600 °C to 800 °C at a heating rate in the range of 0.4 °C/s to 1 °C/s for a time period in the range of 20 minutes to 60 minutes to obtain an annealed film; and
g. maintaining said annealed film for a time period in the range of 20 minutes to 60 minutes, followed by cooling to a temperature in the range of 250 °C to 300 °C, followed by further cooling to a temperature in the range of 20 °C to 40 °C to obtain said thin film.

13. The process as claimed in claim 12, wherein said substrate is selected from the group consisting of silicon, silicon, sapphire (Al₂O₃), magnesium oxide (MgO), gallium nitride (GaN), and silicon carbide (SIC).

14. The process as claimed in claim 12, wherein said insulating material is selected from the group consisting of silicon dioxide (SiO₂) and silicon nitride (SiN).

15. (canceled)

16. The process as claimed in claim 12, wherein said transition metal is at least one selected from the group consisting of titanium and zirconium.

17. The process as claimed in claim 12, wherein said inert atmosphere is at least one selected from the group consisting of argon, helium, and neon.

18. (canceled)

19. The process as claimed in claim 12, wherein said first predetermined deposition rate is in the range of 5 nm/minute to 15 nm/minute.

20. The process as claimed in claim 12, wherein said metal is at least one selected from the group consisting of platinum, iridium, ruthenium, and copper.

21. The process as claimed in claim 12, wherein
said first predetermined temperature is in the range of 900 °C to 1200 °C; and said first predetermined time period is in the range of 60 minutes to 180 minutes;
said second predetermined temperature is in the range of 20 °C to 40 °C and said second predetermined time period is in the range of 2 minutes to 15 minutes; and
said third predetermined temperature is in the range of 20 °C to 40 °C and said third predetermined time period is in the range of 2 minutes to 15 minutes.

22. The process as claimed in claim 12, wherein said second predetermined deposition rate is in the range of 5 nm/minute to 15 nm/minute.

23. A process for developing an array-like pattern on a thin film, said process comprising the following steps:
i. cleaning a top layer of transition metal oxide and metal of said thin film as claimed in claim 1, followed by heating at a temperature in the range of 110 °C to 150 °C for a time period in the range of 3 minutes to 5 minutes to obtain a cleaned thin film;
ii. coating a layer of photoresist material on said cleaned thin film by using a spin coating process at a spinning speed in the range of 3000 rpm to 5000 rpm for a time period in the range of 10 seconds to 50 seconds to obtain a photoresist material coated thin film;
iii. irradiating UV light having a wavelength in the range of 300 nm to 500 nm though a photomask on said photoresist material coated thin film to obtain an UV irradiated thin film;
iv. washing said UV irradiated thin film with a developer solution for a time period in the range of 60 seconds to 90 seconds to remove soluble photoresist material, followed by baking at a temperature in the range of 110 °C to 130 °C for a time period in the range of 30 seconds to 120 seconds, followed by further baking at a temperature in the range of 110 °C to 130 °C for a time period in the range of 10 minutes to 15 minutes to obtain an array like pattern developed thin film; and
v. etching said array-like pattern developed thin film by dissolving it in a mixture of HNO₃:HCl:H₂O solution having a molar ratio of 7:1:8 at a temperature in the range of 60 °C to 80 °C to obtain said array-like pattern on the thin film.

24. The process as claimed in claim 23, wherein said photoresist material is 2-methoxy-1-methyl ethyl acetate (AZ 4000 series).

25. The process as claimed in claim 23, said developer solution comprises:
water in an amount in the range of 97.5 mass % to 98 mass % with respect to the total amount of said solution;
tetramethylammonium hydroxide (TMAH) in an amount in the range of 1.9 mass % to 2.45 mass % with respect to the total amount of said solution; and
polyglycol in an amount in the range of 0.05 mass % to 0.1 mass % with respect to the total amount of said solution.
